(19) United States
(12) Patent Application Publication
(10) Pub. No.: US 2015/0221527 A1
(43) Pub. Date: Aug. 6, 2015

(54) ENCAPSULANT COMPOSITION

(71) Applicant: Rohm and Haas Electronic Materials LLC, Marlborough, MA (US)

(72) Inventors: Paul L. MORGANELLI, Upton, MA (US); Jae-Kyu CHO, Niskayuna, NY (US); Jenna M. CORDERO, Shrewsbury, MA (US)

(21) Appl. No.: 14/604,764

(22) Filed: Jan. 26, 2015

Related U.S. Application Data
(60) Provisional application No. 61/934,698, filed on Jan. 31, 2014.

(51) Int. Cl. H01L 21/56; H01L 23/31; H01L 23/22; C08L 63/00; C08K 3/36

(52) U.S. Cl. CPC H01L 21/56; C08L 63/00; C08K 3/36; H01L 23/22; H01L 23/3128

(57) ABSTRACT

Compositions that have relatively high Tg, relatively low CTE, and relatively low modulus are suitable for use as encapsulants with stress-sensitive electronic assemblies, such as those containing low k dielectrics. These compositions are used in methods of die attachment, encapsulation, and solder bump reinforcement.

This application claims the benefit of priority under 35 U.S.C. §119(e) to U.S. Provisional Application No. 61/934,698, filed Jan. 31, 2014, the entire contents of which are incorporated herein by reference.

The present invention relates to thermosetting resin formulations useful in the manufacture of electronic assemblies, and more particularly to capillary underfill compositions.

Thermosetting resins, most commonly epoxy-based, are often used in the electronics industry for making semiconductor packaging materials. Current epoxy resin formulations used in semiconductor packaging materials include, for example, high purity diglycidyl ether of bisphenol F or diglycidyl ether of bisphenol A along with high performance or multifunctional resins such as the diglycidylether of naphthalene diol or the triglycidylether of para-aminophenol. Epoxy-based compositions are frequently combined with other thermosetting resins such as cyanate ester and maleimides in order to increase stability at high temperatures. Additionally, epoxy-based compositions provide good adhesion, good moisture resistance, can be formulated with various curing agents (e.g. amines, anhydrides, and phenols) to yield high glass transition upon curing, and can be loaded will fillers to reduce coefficient of thermal expansion (CTE). In addition to low CTE and high Tg properties, filled epoxy-based compositions exhibit high stiffness, or modulus owing to their rigid backbone structures. A primary use for epoxy-based compositions in electronic assembly applications has been as capillary underfill, in which the uncured liquid composition is applied along the chip edge and allowed to flow by capillary action into the gap between the chip and substrate. Upon curing, the underfill provides an effective seal to protect the solder connections between the chip and substrate.

Whether epoxy or other thermosetting resins are used, conventional underfill formulation approaches use cross-linkable rigid structures, typically containing aromatic rings. Many formulations are based on high purity bisphenol F or bisphenol A epoxy resins in combination with other high performance or multifunctional aromatic epoxy resins, because such structures impart higher glass transition temperatures (Tg) to the cured resin. Higher Tg reduces bump cracking in assemblies that experience thermal extremes, often assessed by thermal cycle testing. High performance resins also tend to increase the stiffness, or modulus, of the cured underfill. While high modulus materials again protect delicate solder bumps during thermal cycling, they tend to increase the stress on the dielectric materials which protect part of the circuitry of the flip chip. Increased stress negatively impacts the dielectric layer by causing it to crack, especially in assemblies with thin die, because thin die are often built with ultra-low k dielectric materials that are increasingly sensitive to stress. The trend in electronic packaging designs to use low k dielectrics, that is, having a dielectric constant of ≦3.5, requires the development of high Tg underfills with lower modulus to reduce stress. Many large assemblers have set target modulus values at <7 GPa.

Electronic encapsulants are normally highly filled materials. The properties of the filled materials largely depend on the type of filler used and the level of filler loading (or amount of filler in the materials). In general, increasing the filler loading level usually decreases the coefficient of thermal expansion, CTE. While low CTE also protects solder bumps against cracking, the high filler content again increases the modulus and hence the risk of causing cracks to develop in the low k dielectric layers. Thus, highly filled capillary underfill formulations incorporating the digycidyl ethers of rigid aromatic epoxies, such as bisphenol A or bisphenol F, suffer from relatively low reliability in devices containing low k dielectrics.

Attempts have been made to solve certain of these shortcomings. For example, International Pat. App. WO 98/33645 discloses siloxanes having cycloaliphatic epoxy moieties, where the epoxy functionality is attached to a 5-, 6- or 7-membered ring. U.S. Pat. No. 8,008,419 discloses cyclic siloxanes having phenyl-terminated epoxides. In both of these references, the siloxanes have relatively sterically hindered epoxy functionalities and would not react well with amines or phenols at typical underfill cure temperatures (ca. 130-160° C.) used in conventional manufacturing processes. Also, U.S. Pat. No. 8,008,419 describes the phenyl-terminated epoxy siloxanes as high Tg materials, and would have a rigid structure and, accordingly, a high modulus. There remains a need for underfills that have a combination of relatively high Tg, relatively low CTE, and relatively low modulus for use with stress-sensitive electronic assemblies such as those containing low k dielectrics.

The present invention provides a composition comprising: a liquid cyclic siloxane comprising a plurality of glycidyl ether moieties; an aromatic thermosetting resin; and a curing agent. Such composition is particularly suitable for use as a capillary underfill, an encapsulant and as a solder bump reinforcement.

Also provided by the present invention is a method of forming an electronic assembly comprising: providing an electronic component and a substrate, wherein one of the electronic component and the substrate has a plurality of interconnect structures and the other has a plurality of conductive bonding pads; electrically connecting the electronic component and the substrate; forming an underfill composition between the electronic component and the substrate; and curing the underfill composition; wherein the underfill composition comprises a liquid cyclic siloxane comprising a plurality of glycidyl ether moieties; an aromatic thermosetting resin; and a curing agent.

The present invention further provides an electronic assembly comprising an electronic component electrically connected to a substrate having a cured underfill composition between the electronic component and the substrate, wherein the underfill composition comprises a reaction product of a liquid cyclic siloxane comprising a plurality of glycidyl ether moieties; an aromatic thermosetting resin; and a curing agent.

As used throughout this specification, the following abbreviations shall have the following meanings, unless the context clearly indicates otherwise: ° C.=degree Centigrade; min.=minute; Hz=hertz; TMA=thermomechanical analysis; ppm=part per million; ca.=approximately; wt %=weight percent; g=gram; mg=milligram; and μm=micron=micrometer. All amounts are percent by weight and all ratios are molar ratios, unless otherwise noted. All numerical ranges are inclusive of the end points and combinable in any order, except where it is clear that such numerical ranges are constrained to add up to 100%. The term “(meth)acrylate” includes acrylate and methacrylate. As used herein, “high Tg” refers to a Tg value of ≧100° C.

The present compositions comprise a liquid cyclic siloxane comprising a plurality of glycidyl ether moieties; an aromatic thermosetting resin; a curing agent; optionally an inorganic filler; optionally one or more additional epoxy components; and optionally a catalyst. The present compositions may also optionally contain one or more of rheology modifiers, filler dispersants, pigments, adhesion promoters, and mixtures thereof.

A variety of cyclic siloxanes may be used in the present invention. Preferred cyclic siloxanes are cyclotrisiloxanes (D3), cyclotetrasiloxanes (D4), cyclopentasiloxanes (D5), and cyclohexasiloxanes (D6). More preferably, the cyclic siloxane is a cyclotrisiloxane or a cyclotetrasiloxane. The present cyclic siloxane comprises at least 2 glycidyl ether moieties, preferably at least 3 glycidyl ether moieties, and more preferably at least 4 glycidyl ether moieties. It is further preferred that every silicon atom in the siloxane ring is substituted with a glycidyl ether moiety or a (meth)acrylate moiety, where the siloxane comprises at least 2 glycidyl ether moieties. Preferably, cyclic siloxane has the formula

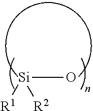

wherein each R¹ is independently H or C₁-C₆alkyl; each R² is independently chosen from C₁-C₆alkyl, C₂-C₆alkenyl,

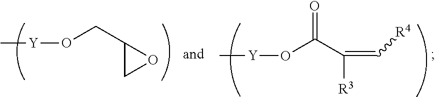

each Y is independently chosen from a chemical bond, C₁-C₆alkylene, C₂-C₆alkylidene, and C₂-C₆alkenylene; each of R³ and R⁴ is independently chosen from H and C₁-C₆alkyl; and n=3 to 6; wherein at least 2 R² groups are

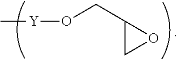

It is preferred that each R¹ is independently H or C₁-C₃alkyl, more preferably each R¹ is independently H or methyl, and still more preferably each R¹ is H or methyl. When R² is alkyl, it is preferably C₁-C₄alkyl. Preferably, each R² is independently chosen from

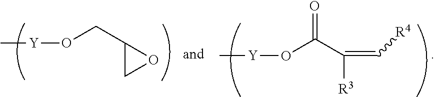

It is preferred that each R³ is independently H or C₁-C₄alkyl, and more preferably H or methyl. Preferably, each R⁴ is independently H or C₁-C₄alkyl, more preferably H or methyl, and yet more preferably H. Y is preferably C₁-C₆alkylene, C₂-C₆alkylidene, and C₂-C₆alkenylene, more preferably C₁-C₄alkylene, C₂-C₆alkylidene, and C₂-C₆alkenylene, and yet more preferably C₁-C₄alkylene. Preferably, n=3 or 4. It is preferred that at least 3 R² groups, and more preferably at least 4 R² groups are

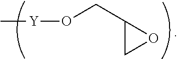

Particularly useful cyclic siloxanes are those of Structures I and II below, where each R¹ is independently chosen from H and methyl; and more preferably each R¹ is H or methyl.

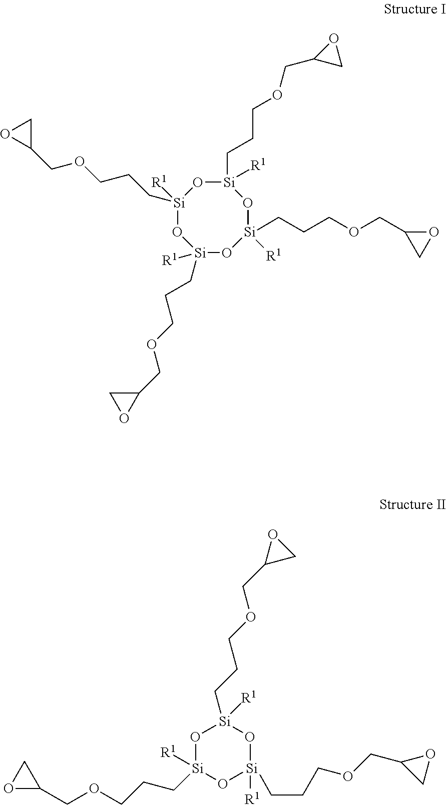

Another useful cyclic siloxane is shown by Structure III. Cyclic siloxanes containing a

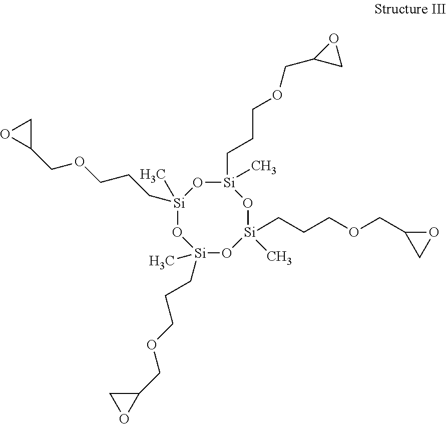 [SMILES: C[Si]1(CCCOCC2CO2)O[Si](C)(CCCOCC2CO2)O[Si](C)(CCCOCC2CO2)O[Si](C)(CCCOCC2CO2)O1]

(meth)acrylate moiety in combination with glycidyl ether moieties are particularly useful in compositions containing an amine hardener, or compositions catalyzed with a combination of imidazole and free-radical initiator, or cured with an anhydride.

The amount of the cyclic siloxane used in the present compositions depends on the amounts of the other composition components in the composition. In general, the cyclic siloxane is used in an amount of from 2 to 80 wt %, preferably from 5 to 60 wt %, and more preferably from 10 to 50 wt %, based on the total weight of the resin (the cyclic siloxane and the other thermosetting resin components).

A wide variety of relatively high Tg thermosetting resins may be used in the present invention. As used herein, the term “relatively high Tg thermosetting resin” refers to a thermosetting resin having, upon curing, a Tg of ≧100° C., and preferably ≧120° C., as measured by TMA. Preferred relatively high Tg thermosetting resins are multifunctional epoxies, particularly those with aromatic structures, and cyanate ester resins. “Cyanate ester resins” refer to aromatic resins, such as phenolic or novolac resins, containing a cyanate (—OCN) substituent on an aromatic ring. Suitable epoxy resins include, without limitation: difunctional epoxies which may be aromatic or aliphatic; trifunctional epoxies which may be aromatic or aliphatic; and monofunctional aromatic epoxies. Exemplary difunctional epoxies are: diglycidyl ether of Bisphenol A; diglycidyl ether of Bisphenol F; diglycidyl ether of di-hydroxy naphathalene; resorcinol diglycidyl ether; and the like. Exemplary trifunctional epoxies are: triglycidyl hydroxyl aniline; tris-(2,3-epoxypropyl)-isocyanurate; and the like. Exemplary monofunctional aromatic epoxies are: t-butyl phenyl glycidyl ether; cresyl glycidyl ether; and the like. Suitable cyanate ester resins include, without limitation, difunctional and polyfunctional cyanate ester resins. Exemplary cyanate ester resins include resins formed from: bis(4-cyanatophenyl)methane; 1,4-dicyanatobenzene; 4,4′-ethylidenediphenyl dicyanate; and the like. it is preferred that the aromatic thermosetting resin is a cyanate ester resin.

The relatively high Tg thermosetting resins useful in the present invention are generally commercially available from a variety of sources. Such thermosetting resins may be used as is, or may be further purified using any suitable technique. In general, the relatively high Tg thermosetting resins are used in the present compositions in an amount of from 20 to 80 wt %, preferably from 25 to 65 wt %, and more preferably from 30 to 60 wt %, based on the total weight of the resin (cyclic siloxane and other thermosetting resin components).

Optionally, a wide variety of relatively low viscosity epoxy resins may be used as diluents (epoxy diluents) for the invention compositions. As used herein, the term “relatively low viscosity epoxy resins” means epoxy resins having a viscosity of <500 cP/25° C. Suitable epoxy diluents include, without limitation: hydrogenated diglycidyl ether of Bisphenol A/F; trimethylolpropanetriglycidyl ether; hexanedioldiglycidyl ether; cyclohexane dimethanol diglycidyl ether; and the like. When used, such epoxy diluents are used in an amount of ≦15 wt % and preferably ≦10 wt %, based on total resin content.

Curing agents (or hardeners) useful in the present invention are any suitable epoxy curing agents known in the art, which are suitable for curing (polymerizing) epoxy resins. Exemplary curing agents include, without limitation, dicyandiamide, substituted guanidines, phenolics, amino, benzoxazine, anhydrides, amido amines, polyamides, polyamines, aromatic amines, aliphatic amines, polyesters, polyisocyanates, polymercaptans, urea formaldehyde and melamine formaldehyde resins, imidazoles, transition metal chelates, and mixtures thereof. In compositions not containing cyanate ester, the curing agent is preferably an aromatic amine Preferred curing agents include: methylene-bis(o-ethyl aniline); diethyltoluene diamine; diaminodiphenyl sulfone; diaminodiphenyl sulfide; and their alkylated derivatives. Mixtures of curing agents, such as mixtures or aromatic amines, may be used in the present invention. The amount of the amine curing agent in the present invention depends on stoichiometric considerations (molar ratio) of total epoxy resin. A typical molar ratio of epoxy to curing agent is 1:0.5 to 1:2, more preferably 1:0.8 to 1:1.5, and most preferably 1:0.9 to 1:1.1.

In compositions containing cyanate ester, the preferred curing agent is a transition metal chelate. Preferred metal chelates are copper acetylacetonate, cobalt acetylacetonate, and the like. Optionally, an imidazole may be combined with the metal chelate to increase the cure speed and lower the cure temperature. Preferred imidazoles are cyano-2-ethyl-4-methyl imidazole, 2-phenyl imidazole, 2-phenyl-4-methyl imidazole, and the like. When present, the concentration of the transition metal chelate is generally from 0.05 to 10 wt %, preferably from 0.1 to 5 wt %, and most preferably from 0.15 to 1 wt % based on the total weight of the composition. The transition metal chelate level can be adjusted to allow adequate processing in the final application.

Optionally, the present compositions may comprise a filler, and preferably do comprise an filler. Filler is used to lower the overall CTE of the underfill. The filler used in the present invention is non-conductive and inert, that is, it will not react with or destabilize the underfill composition. Preferably, an inorganic filler is used. Suitable filler includes, without limitation, silica, metal oxides, ceramics, hollow fillers, and other organic or inorganic particulate filler. Suitable ceramic inorganic fillers are crystalline or amorphous oxides, nitrides or carbides, such as, but not limited to, zirconia, berylia, ceria, aluminum nitride, boron nitride, silicon carbide, and silicon nitride. It is preferred that the inorganic filler is chosen from silica, alumina, zirconia, berylia, ceria, zinc oxide, silicon nitride, aluminum nitride, boron nitride, and silicon carbide, and more preferably silica, alumina, and boron nitride. More preferably, the inorganic filler is silica, whether fused, natural or synthetic. Mixtures of inorganic filler may be used. The surface of the fillers may optionally be treated with a coupling agent, which is typically organic, to improve filler and polymer interaction. The filler may have any suitable shape and size. Preferably, the filler has a spherical or substantially spherical shape. Such spherical shape minimizes surface area and allows for a higher loading of filler in the underfill composition. It is preferred that the inorganic filler has a mean particle size of 0.005 to 10 μm, more preferably from 0.01 to 5 μm, and yet more preferably 0.01 to 3 μm. An amount of filler is used in the composition in order to more closely match the CTE of the underfill to the relatively lower CTE of the component (e.g., silicon in the case of a silicon wafer) for silicon to silicon bonding, or between the relatively lower CTE of the component (e.g., silicon) and the relatively higher CTE of an organic substrate (such as a printed circuit board, e.g., FR4). The proper choice of CTE is necessary for stress mitigation during manufacturing and subsequent use of the electronic assembly. The amount of filler used in the present invention may range from 20 to 80 wt %, preferably from 40 to 80 wt %, more preferably from 50 to 75 wt %, and still more preferably from 55 to 70 wt %, based on the total weight of the composition.

A catalyst may optionally be added to the compositions of the invention. Generally, any homogeneous or heterogeneous catalyst known in the art which is appropriate for facilitating the reaction between an epoxy resin and a hardener may be used. The catalyst may include, but is not limited to, imidazoles, tertiary amines, phosphonium complexes, Lewis acids such as boron trifluoride complexes, or Lewis bases such as tertiary amines like diazabicycloundecene and 2-phenylimidazole, transition metal chelates, quaternary salts such as tetrabutyphosphonium bromide and tetraethylammonium bromide, organoantimony halides such as triphenylantimony tetraiodide and triphenylantimony dibromide, and mixtures thereof. When present, the concentration of the catalyst is generally from 0.01 to 10 wt %, preferably from 0.1 to 5 wt %, and most preferably from 0.15 to 1 wt % based on the total weight of the composition. The catalyst level can be adjusted to allow adequate processing in the final application.

Other optional components that may be useful in the present compositions are components normally used in resin formulations known to those skilled in the art. For example, the optional other components may comprise flame retardants, diluents, stabilizers, compounds that can be added to the composition to enhance application properties (for example, surface tension modifiers or flow aids), reliability properties (for example, adhesion promoters) the reaction rate, the selectivity of the reaction, and/or the catalyst lifetime, and the like. The amounts of such other optional components used in the compositions of the invention are those conventionally used in epoxy compositions.

Compositions of the invention may be prepared by blending a cyclic siloxane comprising a plurality of glycidyl ether moieties; an aromatic thermosetting resin, curing agent, and any other optional ingredients as desired. Such blending may be achieved through the use of a Ross PD Mixer (Charles Ross), with or without vacuum. All the components of the compositions of the invention are typically mixed and dispersed at a temperature enabling the preparation of an effective composition, generally from 20 to 80° C., and preferably from 25 to 35° C. Lower mixing temperatures help to minimize reaction of the resin and curing agent components to maximize the pot life of the composition. The blended components are typically stored at sub-ambient temperatures to maximize shelf life. Acceptable temperature ranges are, for example, from −100 to 25° C., more preferably from −70 to 10° C., and even more preferably from −50 to 0° C.

The compositions of the invention are useful in a variety of applications in the manufacture of electronic devices, such as underfills, encapsulants and solder bump reinforcement. An electronic assembly may be formed by providing an electronic component and a substrate, wherein one of the electronic component and the substrate has a plurality of interconnect structures and the other has a plurality of conductive bonding pads; electrically connecting the electronic component and the substrate; forming an underfill composition between the electronic component and the substrate; and curing the underfill composition; wherein the underfill composition comprises a liquid cyclic siloxane comprising a plurality of glycidyl ether moieties; an aromatic thermosetting resin; and a curing agent. The present compositions may be cured by any suitable means, such as by heating at a suitable temperature to cause the compositions to cure.

In one embodiment, the compositions of the invention may be used as capillary underfill encapsulants in semiconductor packaging materials, such as to protect fragile electronic components, such as flip chip ball grid array (FC-BGA) and chip-scale packages (CSP). The initial step in this process is to apply the underfill along the edge of the chip. It then flows by capillary action into the gap between the chip and substrate. The underfill is subsequently cured in an oven, typically in the temperature range of 140-170° C., to create a thermoset reinforcement of the chip to substrate connections. The cured composition must cure free of voids in order to prevent solder extrusions that can bridge between two bumps, creating a short-circuit.

The cured compositions (that is, the cross-linked product made from the curable composition) of the present invention, such as when used as an underfill, show an advantage over cured conventional, epoxy-based underfills. The cured composition of the present invention provides relatively high Tg in combination with relatively low CTE and relatively low modulus. Generally, the Tg of the cured resin compositions of the invention is ≧100° C., and preferably ≧120° C., as measured by TMA. This is attributed to the high cross-linking density of the cyclic siloxane structure. However the modulus of the cured compositions is seen to decrease as the content of the epoxy siloxane increases, with very little decrease in Tg value. The CTE of the cured compositions of the invention is typically ≦35 ppm/° C., preferably <35 ppm/° C., more preferably ≦32 ppm/° C., and yet more preferably ≦30 ppm/° C. For example, cured compositions of the present invention filled at 60-65 wt % with silica typically have a CTE in the range of 28-35 ppm/° C. Cured compositions of the invention have a modulus of <7.5, and preferably ≦7.

The following components are used in the Examples described below: epoxy modified siloxane (CS-697, structure I) manufactured by Designer Molecules, Inc; DGEBF epoxy (Epiclon 830 LVP) manufactured by DIC; 4,4′-ethylidenediphenyl dicyanate (Primaset LECy) manufactured by Lonza; trigycidyl hydroxyaniline (JER 630 LSD), manufactured by Mitsubishi; cyclohexanedimethanol diglycidylether (CHDM), manufactured by Dow Chemical); diethylenetoluene diamine (Ethacure 100), manufactured by Albermarle; methylene bis(o-ethyl aniline) (Aceto MBOEA), manufactured by Aceto Corp; spherical silica (SFP-130MC), manufactured by Denka, and (SO-E2), manufactured by Admatechs; 2-ethyl-4-methyl imidazole (2E4MZ), sold by Aldrich Chemical; copper acetylacetonate (Cu AcAc), sold by Aldrich; filler dispersant (BYK W-969), available from BYK Chemie; and glycidoxypropyltrimethoxysilane (Z-6040), manufactured by Dow Corning.

The following test methods are used in the following examples: CTE and Tg values of cured materials were determined using thermomechanical analysis on a TMA instrument (available from TA instruments), with 10° C./min ramp rate. A relaxation scan to 200° C. was used prior to obtaining the final measurement. Modulus values were obtained using dynamic mechanical analysis on a DMA instrument (available from TA Instruments), using single cantilever beam geometry running at 0.1% strain and 1 Hz.

### EXAMPLES 1-3

In each example, epoxy-modified siloxane (Structure I) is combined with DGEBF epoxy, triglycidyl hydroxyaniline, cyclohexanedimethanol diglycidylether, DETDA, and methylene bis(o-ethylaniline). Components were mixed at 2000 rpm/45 sec using a spin-mixer. Silica was added in three equal increments, dispersing each increment with the spin mixer at 2000 rpm/45 sec. The final compositions were milled with a three-roll mill with 5 um roller spacing. Sample C1 contained no cyclic siloxane and was comparative. Examples 1-3 show that with increasing epoxy-modified siloxane content, it is possible to maintain the property of high Tg (>120° C.), while lowering modulus of cured compositions to less than 7.0 GPa. CTE values increased only slightly with loading levels up to 10 wt % epoxy-modified siloxane (based on resin). The weights of the components used, as well as the CTE, modulus and Tg values are reported in Table 1.

TABLE 1

| Example: | C1 | 1 | 2 | 3 |
|---|---|---|---|---|
| Epoxy-modified siloxane | 0 | 6 | 10 | 20 |
| content (resin %) | | | | |
| DGEBF epoxy | 10.42 | 10.13 | 9.74 | 8.20 |
| Triglycidyl hydroxyaniline | 8.43 | 6.70 | 6.22 | 5.60 |
| Cyclohexanedimethanol | 5.32 | 5.32 | 4.89 | 3.80 |
| diglycidylether | | | | |
| Epoxy modified siloxane | 0 | 2.1 | 3.5 | 7.00 |
| (Structure I) | | | | |
| DETDA | 4.82 | 4.74 | 4.57 | 4.41 |
| Methylene bis(o-ethyl aniline) | 5.22 | 5.22 | 5.27 | 5.20 |
| Silica, (Denka SPF-130MC) | 65 | 65 | 65 | 65 |
| CTE, alpha1 (ppm/° C.) | 27.3 | 28.4 | 30.8 | 34.8 |
| CTE, alpha2 (ppm/° C.) | 96.9 | 93.4 | 97.2 | 102.3 |
| Modulus@30° C. | 7.5 | 7.3 | 6.8 | 6.7 |
| Tg, (TMA, ° C.)) | 127 | 125 | 126 | 122 |

### EXAMPLE 4

Table 2 shows the composition and test results of Example 4, comprising cyanate ester, epoxy, catalyst, and epoxy-modified. Examples 4 was prepared by mixing 4,4′-ethylidenediphenyl dicyanate (Primaset LECy L-10) with copper acetylacetonate at 70° C., then adding epoxy-modified siloxane, 2-ethyl-4-methyl imidzole, dispersants (BYK-W-969 and BYK-A-530), and Z-6040 from Dow Corning and mixing at 2000 rpm/45 sec with a Thinky spin mixer. Spherical silica was then added in three equal increments, mixing each fraction at 2000 rpm/45 sec using a spin mixer, and finally roll-milling with a three-roll mill with 5 μm roller spacing. Test samples were cured at 175° C. for 3 hours. Results for Example 4 show it was possible to obtain a modulus below 6 GPa, with Tg>120° C. and CTE<33 ppm/° C.

TABLE 2

| Components | Example 4 |
|---|---|
| Primaset LECy | 19 |
| Epoxy-modified siloxane | 19 |
| 2E4MZ | 1.3 |
| CuAcAc | 0.02 |
| BYK W-969 | 0.8 |
| Spherical silica (SO-E2) | 60 |
| BYK A-530 | 0.4 |
| Properties | |
| CTE. α1, ppm/° C. | 33.32 |
| CTE, α2, ppm/° C. | 81.99 |
| Tg, ° C. (TMA) | 123.65 |
| Modulus @25° C., GPa | 5.7 |

What is claimed is:

1. A composition suitable for use as a capillary underfill comprising: a liquid cyclic siloxane comprising a plurality of glycidyl ether moieties; an aromatic thermosetting resin; and a curing agent.

2. The composition of claim 1 further comprising one or more components selected from additional resins, fillers, catalysts, flame retardants, diluents, and stabilizers.

3. The composition of claim 1 wherein the cyclic siloxane has the formula 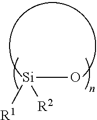
wherein each R¹ is independently H or C₁-C₆alkyl; each R² is independently chosen from C₁-C₆alkyl, C₂-C₆alkenyl, 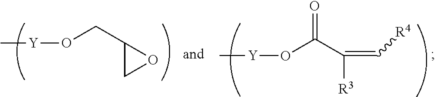
each Y is independently chosen from a chemical bond, C₁-C₆alkylene, C₂-C₆alkylidene, and C₂-C₆alkenylene; each of R³ and R⁴ is independently chosen from H and C₁-C₆alkyl; and n=3 to 6; wherein at least 2 R² groups are

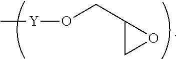

4. The composition of claim 1 further comprising an inorganic filler in an amount of 10 to 85 wt %.

5. The composition of claim 4 wherein the inorganic filler is selected from the group consisting of oxides, nitrides and carbides.

6. The composition of claim 5 wherein the inorganic filler is selected from the group consisting of silica, alumina, zirconia, berylia, ceria, zinc oxide, silicon nitride, aluminum nitride, boron nitride, and silicon carbide.

7. The composition of claim 1 wherein the curing agent is an aromatic amine.

8. A method of forming an electronic assembly comprising: providing an electronic component and a substrate, wherein one of the electronic component and the substrate has a plurality of interconnect structures and the other has a plurality of conductive bonding pads; electrically connecting the electronic component and the substrate; forming an underfill composition between the electronic component and the substrate; and curing the underfill composition; wherein the underfill composition comprises a liquid cyclic siloxane comprising a plurality of glycidyl ether moieties; an aromatic thermosetting resin; and a curing agent.

9. The method of claim 8 wherein the underfill composition further comprises an inorganic filler in an amount of 10 to 85 wt %.

10. The method of claim 9 wherein the inorganic filler is selected from the group consisting of oxides, nitrides and carbides.

11. The method of claim 8 wherein the cyclic siloxane has the formula 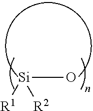
wherein each R¹ is independently H or C₁-C₆alkyl; each R² is independently chosen from C₁-C₆alkyl, C₂-C₆alkenyl, 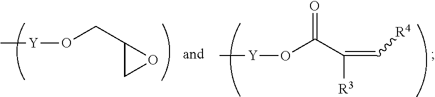
each Y is independently chosen from a chemical bond, C₁-C₆alkylene, C₂-C₆alkylidene, and C₂-C₆alkenylene; each of R³ and R⁴ is independently chosen from H and C₁-C₆alkyl; and n=3 to 6; wherein at least 2 R² groups are [chemical structure]
